(19) United States
(12) Patent Application Publication
(10) Pub. No.: US 2024/0260425 A1
(43) Pub. Date: Aug. 1, 2024

(54) DISPLAY APPARATUS HAVING A DISPLAY PANEL AND AN EYEPIECE

(71) Applicant: LG Display Co., Ltd., Seoul (KR)

(72) Inventors: Hee Cheol KIM, Paju-si (KR); Dong Yeon KIM, Paju-si (KR); Ju Hoon JANG, Paju-si (KR)

(21) Appl. No.: 18/530,094

(22) Filed: Dec. 5, 2023

(30) Foreign Application Priority Data
Jan. 30, 2023 (KR) 10-2023-0011965

(51) Int. Cl. H10K 59/80

(52) U.S. Cl. CPC H10K 59/879; H10K 59/8792

(57) ABSTRACT

A display apparatus including a display panel and an eyepiece is provided. The eyepiece may include a right-eye lens corresponding to a right eye of a user and a left-eye lens corresponding to a left eye of the user. The display panel may provide a right-eye image through the right-eye lens and a left-eye image through the left-eye lens. The display panel may include an encapsulation structure covering light-emitting devices, a black matrix on the encapsulation structure, and optical lenses on the black matrix. The black matrix may extend in a first direction and a second direction perpendicular to the first direction between the light-emitting devices. Each of the optical lenses may extend in the second direction. Each of the optical lenses may overlap at least two light-emitting devices adjacent in the first direction and a portion of the black matrix disposed between the corresponding light-emitting devices. Thus, in the display apparatus, an overlap between a right-eye image and a left-eye image provided to the user by a single-display panel may be minimized or reduced.

### CROSS-REFERENCE TO RELATED APPLICATIONS

This application claims the benefit of Korean Patent Application No. 10-2023-0011965, filed on Jan. 30, 2023, which is hereby incorporated by reference as if fully set forth herein.

### BACKGROUND

### Technical Field

The present disclosure relates to a display apparatus providing a right-eye image and a left-eye image, which are realized by a single display panel, to a right eye and a left eye of a user through an eyepiece, respectively.

### Description of the Related Art

Generally, a display apparatus provides an image to user. For example, the display device may include a plurality of light-emitting devices. Each of the light-emitting devices may emit light displaying a selected color. For example, each of the light-emitting devices may have a stacked structure of a first electrode, a light-emitting layer and a second electrode.

The display apparatus may provide different images to a right eye and a left eye of a user. For example, the display apparatus may include a display panel including the light-emitting devices, a right-eye lens through which a first light emitted from the display panel passes, and a left-eye lens through which a second light emitted from the display panel passes. The first light passing through the right-eye lens may realize a right-eye image provided to the right eye of the user. The second light passing through the left-eye lens may realize a left-eye image provided to the left eye of the user.

### BRIEF SUMMARY

Accordingly, the present disclosure is directed to a display apparatus that substantially obviates one or more problems due to limitations and disadvantages of the related art.

A benefit of the present disclosure is to provide a display apparatus capable of minimizing or reducing an overlap between the right-eye image and the left-eye image provided to the user by a single-display panel, without increasing overall thickness.

Additional advantages, benefits, and features of the disclosure will be set forth in part in the description which follows and in part will become apparent to those having ordinary skill in the art upon examination of the following or may be learned from practice of the disclosure. The benefits and other advantages of the disclosure may be realized and attained by the structure particularly pointed out in the written description and claims hereof as well as the appended drawings.

To achieve these benefits and other advantages and in accordance with the purpose of the present disclosure, as embodied and broadly described herein, there is provided a display apparatus comprising a display panel. The display panel provides a right-eye image through a right-eye lens and a left-eye image through a left-eye lens. The left-eye lens is spaced apart from the right-eye lens. the left-eye lens is disposed side by side with the right-eye lens. The display panel includes light-emitting devices, an encapsulation unit or structure, a black matrix and optical lenses. The light-emitting devices are disposed side by side on a device substrate. The encapsulation unit covers the light-emitting devices. The black matrix is disposed on the encapsulation unit. The black matrix extends between the light-emitting devices in a first direction and a second direction. The second direction is perpendicular to the first direction. The optical lenses are disposed on the black matrix. Each of the optical lenses extends in the second direction. Each of the optical lenses overlaps at least two light-emitting devices adjacent in the first direction. The black matrix includes a first region disposed between the light-emitting devices overlapping with each optical lens.

An edge of each optical lens may be disposed between two light-emitting devices adjacent in the first direction. The black matrix may include a second region overlapping with the edge of each optical lens.

The first region of the black matrix may have a thickness smaller than each optical lens.

The first region of the black matrix may have a side surface of a concave shape.

A thickness of the black matrix may be the same as a thickness of each optical lens.

The display panel may include color filters. The color filters may be disposed between the light-emitting devices and the optical lenses. The color filters may be disposed on a layer different from the black matrix.

Each of the color filters may include a region overlapping with the first region of the black matrix.

The display panel may include a color planarization layer covering the color filters. The black matrix may be disposed on the color planarization layer. An upper surface of the color planarization layer toward the black matrix may be parallel to an upper surface of the encapsulation unit toward the color filters.

The display panel may include a lens passivation layer covering the optical lenses. A refractive index of the lens passivation layer may be greater than a refractive index of each optical lens.

The right-eye lens and the left-eye lens may be coupled to a device body. The display panel may be accommodated in the device body. The display panel may be disposed between the right-eye lens and the left-eye lens.

A mounting element may be coupled to an edge of the device body. The mounting element may extend in a direction from the edge of the device body.

A first light emitted from the display panel to realize the right-eye image may be reflected toward the right-eye lens by a right-eye mirror. A second light emitted from the display panel to realize the left-eye image may be reflected toward the left-eye lens by a left-eye mirror. The right-eye mirror and the left-eye mirror may be disposed within the device body.

The right-eye mirror and the left-eye mirror may be aspheric mirror.

The device body may include a first sidewall and a second sidewall. The right-eye lens and the left-eye lens may be coupled in the first sidewall. The second sidewall may be opposite to the first sidewall. The display panel may be disposed closer to the first sidewall than the second sidewall. The right-eye mirror and the left-eye mirror may be disposed closer to the second sidewall than the first sidewall.

A distance between the right-eye mirror and the display panel may be larger than a distance between the right-eye lens and the display panel.

A distance between the left-eye mirror and the display panel may be larger than a distance between the left-eye lens and the display panel.

To achieve the benefits and other advantages and in accordance with the purpose of the present disclosure, as embodied and broadly described herein, there is provided a display panel. The display panel includes: a device substrate and a plurality of light-emitting devices on the device substrate. The plurality of light-emitting devices includes: a first light-emitting device; and a second light-emitting device adjacent the first light-emitting device along a first direction. The display panel further includes: a black matrix on the plurality of light-emitting devices, the black matrix including a first region between the first light-emitting device and the second light-emitting device, the first region extending in a second direction transverse the first direction; and an optical lens extending in the second direction and being over and covering the first light-emitting device, the second light-emitting device and the first region of the black matrix.

To achieve the benefits and other advantages and in accordance with the purpose of the present disclosure, as embodied and broadly described herein, there is provided a display device. The display apparatus includes: a first lens; a second lens spaced from the first lens; a first mirror operable to reflect first light toward the first lens to realize a first image; a second mirror operable to reflect second light toward the second lens to realize a second image; and a display panel between the first lens and the second lens, the display panel being operable to generate the first light and the second light. The display panel includes: a device substrate; a first light-emitting device on the device substrate; a second light-emitting device on the device substrate, the second light-emitting device being adjacent the first light-emitting device along a first direction; a black matrix on first and second light-emitting devices, the black matrix including a first region between the first light-emitting device and the second light-emitting device, the first region extending in a second direction transverse the first direction; and an optical lens extending in the second direction and being over and covering the first light-emitting device, the second light-emitting device and the first region of the black matrix.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view schematically showing an inside of a device body in the display apparatus according to the embodiment of the present disclosure;

FIG. 3 is a view showing a partial top surface of a display panel in the display apparatus according to the embodiment of the present disclosure;

FIG. 4 is a view showing a circuit of a unit pixel area in the display apparatus according to the embodiment of the present disclosure;

FIG. 5 is a view taken along I-I′ of FIG. 3;

FIGS. 6 and 7 are graphs showing relative luminance of a right-eye image and a left-eye image realized by the display apparatus according to a viewing angle according to whether a black matrix is arranged; and

FIGS. 8 to 10 are views showing the display panel in the display apparatus according to another embodiment of the present disclosure.

### DETAILED DESCRIPTION

Hereinafter, details related to the above benefits, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or mostly similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless “directly” is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

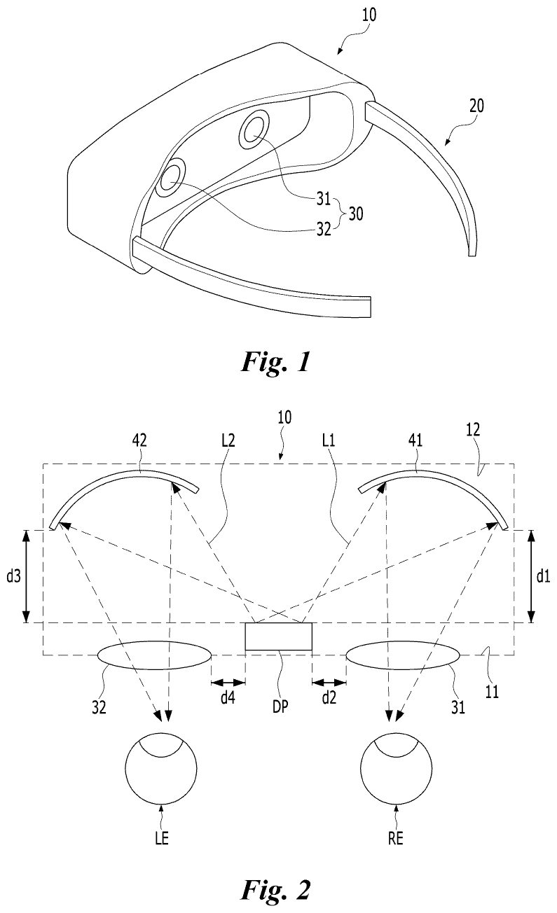

FIG. 1 is a view schematically showing a display apparatus according to an embodiment of the present disclosure. FIG. 2 is a view schematically showing an inside of a device body in the display apparatus according to the embodiment of the present disclosure.

Referring to FIGS. 1 and 2, the display apparatus according to the embodiment of the present disclosure may include a device body 10 in which a display panel DP is accommodated and a mounting element 20 coupled to the device body 10.

The display panel DP may generate an image provided to a user. For example, an eyepiece 30 through which light L1 and L2 emitted from the display panel DP passes may be coupled to the device body 10. The display panel DP may provide different images to a right eye RE and a left eye LE of the user. For example, the eyepiece 30 may include a right-eye lens 31 corresponding to the right eye RE of the user and a left-eye lens 32 corresponding to the left eye LE of the user. The image provided to the user by the display panel DP may be an image for virtual reality (VR) or augmented reality (AR).

The left-eye lens 32 may be spaced from the right-eye lens 31. The left-eye lens 32 may be disposed side by side with the right-eye lens 31. For example, the right-eye lens 31 and the left-eye lens 32 may be coupled to a first sidewall 11 of the device body 10. The first side wall 11 of the device body 10 may have a space between the right-eye lens 31 and the left-eye lens 32. The display panel DP may be disposed between the right-eye lens 31 and the left-eye lens 32.

The right-eye lens 31 and the left-eye lens 32 may be fixed or positioned in front of the right eye RE and the left eye LE of the user by the mounting element 20. The mounting element 20 may be coupled to a side of the device body 10. For example, the mounting element 20 may be coupled to an edge of the first sidewall 11. The mounting element 20 may extend outside of the first sidewall 11. For example, the display apparatus according to the embodiment of the present disclosure may be a head mounted display apparatus (HMD) in the shape of glasses mounted on a user's head. It should be understood that “fixed” does not preclude motion along one or more axes. For example, the right-eye lens 31 and the left-eye lens 32 may be movable to adjust for interpupillary distance (IPD) while still being “fixed” by the mounting element 20.

The display panel DP may emit a first light L1 to realize a right-eye image and a second light L2 to realize a left-eye image. An optical system to provide the right-eye image by the first light L1 to the right eye RE of the user through the right-eye lens 31 and the left-eye image by the second light L2 to the left eye LE of the user through the left-eye lens 32 may be disposed in the device body 10. For example, the optical system may include at least a right-eye mirror 41 reflecting the first light L1 emitted from the display panel DP toward the right-eye lens 31 and a left-eye mirror 42 reflecting the second light L2 emitted from the display panel DP toward the left-eye lens 32. The right-eye mirror 41 and the left-eye mirror 42 may be disposed in the device body 10.

The right-eye mirror 41 may be disposed corresponding to the right-eye lens 31. The left-eye mirror 42 may be disposed corresponding to the left-eye lens 32. A distance d1 between the display panel DP and the right-eye mirror 41 may be greater than a distance d2 between the display panel DP and the right-eye lens 31. A distance d3 between the display panel DP and the left-eye mirror 42 may be greater than a distance d4 between the display panel DP and the left-eye lens 32. For example, the display panel DP may be disposed close to the first sidewall 11 of the device body 10, and the right-eye mirror 41 and the left-eye mirror 42 may be disposed close to a second sidewall 12 of the device body 10 opposite to the first sidewall 11. Each of the right-eye mirror 41 and the left-eye mirror 42 may be an aspheric mirror. In general, a thickness of the display apparatus may be proportional to a distance between the display panel DP and the right-eye lens 41 and a distance between the display panel DP and the left-eye lens 42. This disclosed structure thus provides that as the if the lens can be positioned closer to the display panel, then the overall thickness of the display apparatus can be reduced. Thus, in the display apparatus according to the embodiment of the present disclosure, a thickness of the device body 10 may be reduced and slimmed down, and paths of the first light L1 and the second light L2 emitted from the display panel DP may be sufficiently secured.

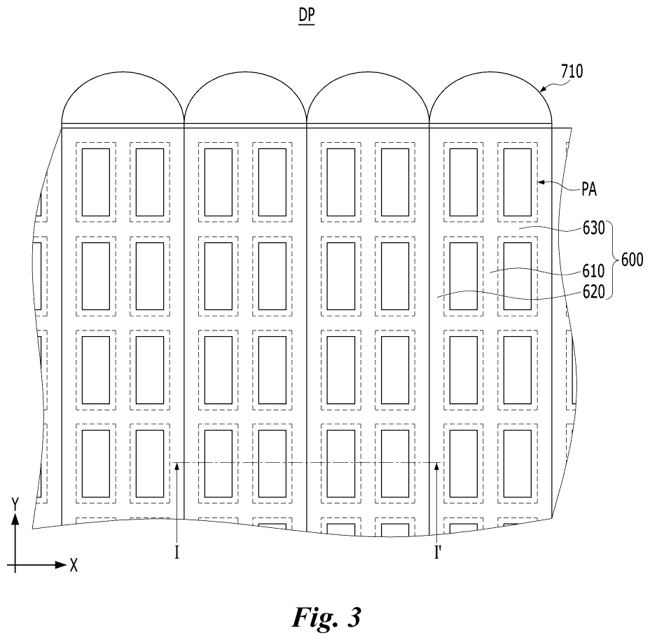

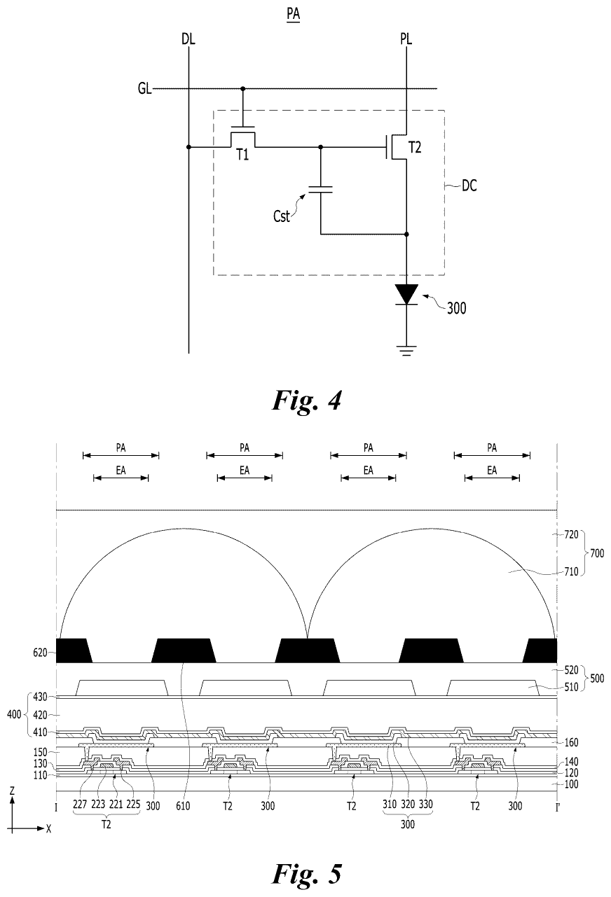

FIG. 3 is a view showing a partial top surface of the display panel in the display apparatus according to the embodiment of the present disclosure. FIG. 4 is a view showing a circuit of a unit pixel area in the display apparatus according to the embodiment of the present disclosure. FIG. 5 is a view taken along I-I′ of FIG. 3.

Referring to FIGS. 3 to 6, in the display apparatus according to the embodiment of the present disclosure, the display panel DP may include a plurality of pixel areas PA. Various signals may be provided in each pixel area PA through signal wirings GL, DL and PL. For example, the signal wirings GL, DL and PL may include a gate line GL applying a gate signal to each pixel area PA, a data line DL applying a data signal to each pixel area PA, and a power voltage supply line PL supplying a power voltage to each pixel area PA.

Each of the pixel areas PA may realize a specific color. For example, a pixel driving circuit DC electrically connected to a light-emitting device 300 may be disposed in each pixel area PA. The pixel driving circuit DC of each pixel area PA may be disposed on a device substrate 100. The device substrate 100 may include an insulating material. For example, the device substrate 100 may include glass or plastic.

The pixel driving circuit DC of each pixel area PA may supply a driving current corresponding to the data signal to the light-emitting device 300 of the corresponding pixel area PA according to gate signal for one frame. For example, the pixel driving circuit DC of each pixel area PA may include a first thin film transistor T1, a second thin film transistor T2 and a storage capacitor Cst.

The first thin film transistor T1 may include a first semiconductor pattern, a first gate electrode, a first drain electrode and a first source electrode. The first thin film transistor T1 may transmit the data signal to the second thin film transistor T2 according to the gate signal. For example, the first thin film transistor T1 may be a switching thin film transistor. The first gate electrode may be electrically connected to the gate line GL, and the first drain electrode may be electrically connected to the date line DL.

The first semiconductor pattern may include a semiconductor material. For example, the first semiconductor pattern may include amorphous silicon (a-Si), polycrystalline silicon (Poly-Si) or an oxide semiconductor, such as IGZO. The first semiconductor pattern may include a first drain region, a first channel region and a first source region. The first channel region may be disposed between the first drain region and the first source region. A resistance of the first drain region and a resistance of the first source region may be smaller than a resistance of the first channel region. For example, the first drain region and the first source region may include a conductive region of an oxide semiconductor. The first channel region may be a region of an oxide semiconductor, which is not conductorized.

The first gate electrode may include a conductive material. For example, the first gate electrode may include a metal, such as aluminum (Al), chrome (Cr), copper (Cu), molybdenum (Mo), titanium (Ti) and tungsten (W). The first gate electrode may be disposed on the first semiconductor pattern. For example, the first gate electrode may overlap the first channel region of the first semiconductor pattern. The first source region and the first drain region of the first semiconductor pattern may be disposed outside the first gate electrode. The first gate electrode may be insulated from the first semiconductor pattern. For example, the first source region of the first semiconductor pattern may be electrically connected to the first drain region of the first semiconductor pattern according to the gate signal.

The first drain electrode may include a conductive material. For example, the first drain electrode may include a metal, such as aluminum (Al), chrome (Cr), copper (Cu), molybdenum (Mo), titanium (Ti) and tungsten (W). The first drain electrode may include a material different from the first gate electrode. The first drain electrode may be disposed on a layer different from the first gate electrode. For example, the first drain electrode may be insulated from the first gate electrode. The first drain electrode may be electrically connected to the first drain region of the first semiconductor pattern.

The first source electrode may include a conductive material. For example, the first source electrode may include a metal, such as aluminum (Al), chrome (Cr), copper (Cu), molybdenum (Mo), titanium (Ti) and tungsten (W). The first source electrode may include a material different from the first gate electrode. The first source electrode may be disposed on a layer different from the first gate electrode. For example, the first source electrode may be disposed on a same layer as the first drain electrode. The first source electrode may include a same material as the first drain electrode. The first source electrode may be insulated from the first gate electrode. For example, the first source electrode may be electrically connected to the first source region of the first semiconductor pattern.

The second thin film transistor T2 may include a second semiconductor pattern 221, a second gate electrode 223, a second drain electrode 225 and a second source electrode 227. The second thin film transistor T2 may generate the driving current corresponding to the data signal. For example, the second thin film transistor T2 may be a driving thin film transistor. The second gate electrode 223 may be electrically connected to the first source electrode of the first thin film transistor T1, and the second drain electrode 225 may be electrically connected to the power voltage supply lines PL.

The second semiconductor pattern 221 may include a semiconductor material. For example, the second semiconductor pattern 221 may include amorphous silicon (a-Si), polycrystalline silicon (Poly-Si) or an oxide semiconductor, such as IGZO. The second semiconductor pattern 221 may include a second channel region between a second drain region and a second source region. The second drain region and a second source region may have a resistance smaller than the second channel region. For example, the second drain region and the second source region may include a conductive region of an oxide semiconductor, and the second channel region may be a region of an oxide semiconductor, which is not conductorized.

The second semiconductor pattern 221 may include a same material as the first semiconductor pattern. The second semiconductor pattern 221 may be disposed on a same layer as the first semiconductor pattern. For example, the second semiconductor pattern 221 may be formed simultaneously with the first semiconductor pattern. A resistance of the second channel region may be the same as a resistance of the first channel region.

The second gate electrode 223 may include a conductive material. For example, the second gate electrode 213 may include a metal, such as aluminum (Al), chrome (Cr), copper (Cu), molybdenum (Mo), titanium (Ti) and tungsten (W). The second gate electrode 223 may include a material different from the first gate electrode 213. The second gate electrode 223 may be disposed on the second semiconductor pattern 221. For example, the second gate electrode 223 may overlap the second channel region of the second semiconductor pattern 221. The second source region and the second drain region of the second semiconductor pattern 221 may be disposed outside the second gate electrode 223. The second gate electrode 223 may be insulated from the second semiconductor pattern 221. For example, the second channel region of the second semiconductor pattern 221 may have an electrical conductivity corresponding to a voltage applied to the second gate electrode 223.

The second gate electrode 223 may include a same material as the first gate electrode. The second gate electrode 223 may be disposed on a same layer as the first gate electrode. For example, the second gate electrode 223 may be formed simultaneously with the first gate electrode.

The second drain electrode 225 may include a conductive material. For example, the second drain electrode 225 may include a metal, such as aluminum (Al), chrome (Cr), copper (Cu), molybdenum (Mo), titanium (Ti) and tungsten (W). The second drain electrode 225 may include a material different from the second gate electrode 223. The second drain electrode 225 may be disposed on a layer different from the second gate electrode 223. For example, the second drain electrode 225 may be insulated from the second gate electrode 223. The second drain electrode 225 may be electrically connected to the second drain region of the second semiconductor pattern 221.

The second drain electrode 225 may be disposed on a same layer as the first drain electrode. The second drain electrode 225 may include a same material as the first drain electrode. For example, the second drain electrode 225 may be formed simultaneously with the first drain electrode.

The second source electrode 227 may include a conductive material. For example, the second source electrode 227 may include a metal, such as aluminum (Al), chrome (Cr), copper (Cu), molybdenum (Mo), titanium (Ti) and tungsten (W). The second source electrode 227 may include a material different from the second gate electrode 223. The second source electrode 227 may be disposed on a layer different from the second gate electrode 223. For example, the second source electrode 227 may be disposed on a same layer as the second drain electrode 225. The second source electrode 227 may include a same material as the second drain electrode 225. The second source electrode 227 may be insulated from the second gate electrode 223. The second source electrode 227 may be electrically connected to the second source region of the second semiconductor pattern 221.

The second source electrode 227 may be disposed on a same layer as the first source electrode. The second source electrode 227 may include a same material as the first source electrode. For example, the second source electrode 227 may be formed simultaneously with the first source electrode.

The storage capacitor Cst may maintain a signal applied to the second gate electrode 223 of the second thin film transistor T2 for one frame. For example, the storage capacitor Cst may be electrically connected between the second gate electrode 223 and the second source electrode 227 of the second thin film transistor T2. The storage capacitor Cst may have a stacked structure of capacitor electrodes. The storage capacitor Cst may be formed using a process of forming the first thin film transistor T1 and the second thin film transistor T2. For example, the storage capacitor Cst may include a first capacitor electrode disposed on a same layer as the second gate electrode 223 and a second capacitor electrode disposed on a same layer as the second source electrode 227.

A plurality of insulating layers 110, 120, 130, 140, 150 and 160 for preventing unnecessary electrical connection in each pixel area PA may be disposed on the device substrate 100. For example, a device buffer layer 110, a gate insulating layer 120, an interlayer insulating layer 130, a device passivation layer 140, a lower planarization layer 150 and a bank insulating layer 160 may be disposed on the device substrate 100.

The device buffer layer 110 may be disposed close to the device substrate 100. The device buffer layer 110 may prevent pollution due to the device substrate 100 in a process of forming the pixel driving circuit DC of each pixel area PA. For example, an upper surface of the device substrate 100 toward the pixel driving circuit DC of each pixel area PA may be completely covered by the device buffer layer 110. The device buffer layer 110 may include an insulating material. For example, the device buffer layer 110 may include an inorganic insulating material, such as silicon oxide (SiOx) and silicon nitride (SiNx). The device buffer layer 110 may include a multi-layer structure. For example, the device buffer layer 110 may have a stacked structure of an inorganic insulating layer made of silicon oxide (SiOx) and an inorganic insulating layer made of silicon nitride (SiNx).

The gate insulating layer 120 may be disposed on the device buffer layer 110. The gate insulating layer 120 may insulate the gate electrodes 223 of each pixel area PA from the corresponding semiconductor pattern 221. For example, the gate insulating layer 120 may cover the first semiconductor pattern and the second semiconductor pattern 221 of each pixel area PA. The first gate electrode and the second gate electrode 223 of each pixel area PA may be disposed on the gate insulating layer 120. The gate insulating layer 120 may include an insulating material. For example, the gate insulating layer 120 may include an inorganic insulating material, such as silicon oxide (SiOx).

The interlayer insulating layer 130 may be disposed on the gate insulating layer 120. The drain electrodes 225 and the source electrodes 227 of each pixel area PA may be insulated from the corresponding gate electrode 223 by the interlayer insulating layer 130. For example, the interlayer insulating layer 130 may cover the first gate electrode and the second gate electrode 223 of each pixel area PA. The first drain electrode, the first source electrode, the second drain electrode 225 and the second source electrode 227 of each pixel area PA may be disposed on the interlayer insulating layer 130. The second capacitor electrode 242 of each pixel area PA may be disposed on the lower interlayer insulating layer 130. The interlayer insulating layer 130 may include an insulating material. For example, the interlayer insulating layer 130 may include an inorganic insulating material, such as silicon oxide (SiOx) and silicon nitride (SiNx).

The device passivation layer 140 may be disposed on the interlayer insulating layer 130. The device passivation layer 140 may prevent damage of the pixel driving circuit DC in each pixel area due to external moisture and impact. For example, the first drain electrode, the first source electrode, the second drain electrode 225 and the second source electrode 227 of each pixel area PA may be covered by the device passivation layer 140. The device passivation layer 140 may include an insulating material. For example, the device passivation layer 140 may include an inorganic insulating material, such as silicon oxide (SiOx) and silicon nitride (SiNx).

The lower planarization layer 150 may be disposed on the device passivation layer 140. For example, the lower planarization layer 150 may remove a thickness difference due to the pixel driving circuit DC of each pixel area PA. For example, an upper surface of the lower planarization layer 150 opposite to the device substrate 100 may be a flat surface. The lower planarization layer 150 may include an insulating material. The lower planarization layer 170 may include a material different from the device passivation layer 140. For example, the lower planarization layer 150 may include an organic insulating material.

The light-emitting device 300 of each pixel area PA may be disposed on the lower planarization layer 150. The light-emitting device 300 of each pixel area PA may emit light displaying a specific color. For example, the light-emitting device 300 of each pixel area PA may include a first electrode 310, a light-emitting layer 320 and a second electrode 330, which are sequentially stacked on the lower planarization layer 150 of the corresponding pixel area PA.

The first electrode 310 may include a conductive material. The first electrode 310 may include a material having a relatively high reflectance. For example, the first electrode 310 may be a metal, such as aluminum (Al) and silver (Ag). The first electrode 310 may have a multi-layer structure. For example, the first electrode 310 may have a structure in which a reflective electrode made of a metal is disposed between transparent electrodes made of a transparent conductive material, such as ITO and IZO.

The light-emitting layer 320 may generate light having luminance corresponding to a voltage difference between the first electrode 310 and the second electrode 330. For example, the light-emitting layer 320 may include an emission material layer (EML) having an emission material. The emission material may include an organic material, an inorganic material or a hybrid material. For example, the display apparatus according to the embodiment of the present disclosure may be an organic light-emitting display apparatus including an organic emission material.

The light-emitting layer 320 may have a multi-layer structure. For example, the light-emitting layer 320 may further include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 may be improved.

The second electrode 330 may include a conductive material. The second electrode 330 may include a material different from the first electrode 310. A transmittance of the second electrode 330 may be higher than a transmittance of the first electrode 310. For example, the second electrode 330 may be a transparent electrode made of a transparent conductive material, such as ITO and IZO, or a translucent electrode in which metals such as Ag and Mg are thinly formed. Thus, in the display apparatus according to the embodiment of the present disclosure, the light generated by the light-emitting layer 320 may be emitted outside through the second electrode 330.

The light-emitting device 300 of each pixel area PA may be electrically connected to the second thin film transistor T2 of the pixel driving circuit DC in the corresponding pixel area PA. For example, the second source electrode 227 of each pixel area PA may be electrically connected to the first electrode 310 of the corresponding pixel area PA. The device passivation layer 140 and the lower planarization layer 150 may include electrode contact holes partially exposing the second source electrode 227 of each pixel area PA. The first electrode 310 of each pixel area PA may be in direct contact with the second source electrode 227 of the corresponding pixel area PA through one of the electrode contact holes. The first electrode 310 of each pixel area PA may be in direct contact with an upper surface of the lower planarization layer 150. Thus, in the display apparatus according to the embodiment of the present disclosure, luminance deviation due to the generating position of the light emitted from each light-emitting device 300 may be prevented.

The bank insulating layer 160 may be disposed on the lower planarization layer 150. The bank insulating layer 160 may define or be adjacent to an emission area EA in each pixel area PA. For example, the bank insulating layer 160 may an edge of the first electrode 310 in each pixel area PA. The light-emitting layer 320 and the second electrode 330 of each pixel area PA may be sequentially stacked on a portion of the corresponding first electrode 310 exposed by the bank insulating layer 160. The bank insulating layer 160 may include an insulating material. For example, the bank insulating layer 160 may include an organic insulating material. The bank insulating layer 160 may include a material different from the lower planarization layer 150. The first electrode 310 of each pixel area PA may be insulated from the first electrode 310 of adjacent pixel area PA by the bank insulating layer 160.

The light emitted from the light-emitting device 300 of each pixel area PA may display a same color as the light emitted from the light-emitting device 300 of adjacent pixel area PA. For example, the light-emitting device 300 of each pixel area PA may emit white light. The light-emitting layer 320 of each pixel area PA may include a same material as the light-emitting layer 320 of adjacent pixel area PA. The light-emitting layer 320 of each pixel area PA may have a same structure as the light-emitting layer 320 of adjacent pixel area PA. For example, the light-emitting layer 320 of each pixel area PA may be formed simultaneously with the light-emitting layer 320 of adjacent pixel area PA. The light-emitting layer 320 of each pixel area PA may be in direct contact with the light-emitting layer 320 of adjacent pixel area PA. For example, the light-emitting layer 320 of each pixel area PA may extend onto the bank insulating layer 160.

A voltage applied to the second electrode 330 of each pixel area PA may be the same as a voltage applied to the second electrode 330 of adjacent pixel area PA. For example, the second electrode 330 of each pixel area PA may be electrically connected to the second electrode 330 of adjacent pixel area PA. The second electrode 330 of each pixel area PA may include a same material as the second electrode 330 of adjacent pixel area PA. For example, the second electrode 330 of each pixel area PA may be formed simultaneously with the second electrode 330 of adjacent pixel area PA. The second electrode 330 of each pixel area PA may be in direct contact with the second electrode 330 of adjacent pixel area PA. For example, the second electrode 330 of each pixel area PA may extend onto the bank insulating layer 160. Thus, in the display apparatus according to the embodiment of the present disclosure, a process of forming the second electrode 330 in each pixel area PA may be simplified. And, in the display apparatus according to the embodiment of the present disclosure, the luminance of the light emitted from the light-emitting device 300 of each pixel area PA may be adjusted by the data signal applied to the pixel driving circuit DC of the corresponding pixel area PA.

An encapsulation unit or structure 400 may be disposed on the light-emitting device 300 of each pixel area PA. The encapsulation unit 400 may prevent damage of the light-emitting devices 300 due to the external moisture and impact. For example, the light-emitting device 300 of each pixel area PA may be completely covered by the encapsulation unit 400. The encapsulation unit 400 may have a multi-layer structure. For example, the encapsulation unit 400 may include a first encapsulating layer 410, a second encapsulating layer 420 and a third encapsulating layer 430, which are sequentially stacked. The first encapsulating layer 410, the second encapsulating layer 420 and the third encapsulating layer 430 may include an insulating material. The second encapsulating layer 420 may include a material different from the first encapsulating layer 410 and the third encapsulating layer 430. For example, the first encapsulating layer 410 and the third encapsulating layer 430 may be an inorganic insulating layer made of an inorganic insulating material, and the second encapsulating layer 420 may be an organic insulating layer made of an organic insulating material. Thus, in the display apparatus according to the embodiment of the present disclosure, the damage of the light-emitting devices 300 due to the external moisture and impact may be effectively prevented. A thickness difference due to the light-emitting devices 300 may be removed by the second encapsulating layer 420. For example, an upper surface of the encapsulation unit 400 opposite to the device substrate 100 may be a flat surface.

Each of the pixel areas PA may realize a color different from adjacent pixel areas PA. For example, a color conversion unit or structure 500 may be disposed on the encapsulation unit 400. The color conversion unit 500 may include a plurality of color filters 510. Each of the color filters 510 may be disposed on one of the pixel areas PA. The color filter 510 of each pixel area PA may be disposed on a path of the light emitted from the light-emitting device 300 of the corresponding pixel area PA. For example, the color filter 510 of each pixel area PA may overlap the emission area EA of the corresponding pixel area PA. The color filter 510 of each pixel area PA may include a material different from the color filter 510 of adjacent pixel areas PA. For example, the plurality of the color filters 510 may include a red color filter disposed on the pixel area PA realizing red color, a blue color filter disposed on the pixel area PA realizing blue color, and a green color filter disposed on the pixel area PA realizing green color. Thus, in the display apparatus according to the embodiment of the present disclosure, the image made of various colors may be provided to the user. The color filter 510 of each pixel area PA may have a size larger than the emission area EA of the corresponding pixel area PA. Therefore, in the display apparatus according to the embodiment of the present disclosure, light leakage due to light which does not pass though the color filter 510 of each pixel area PA may be prevented.

The color conversion unit 500 may include a color planarization layer 520 covering the color filters 510. A thickness difference due to the color filter 510 of each pixel area PA may be removed by the color planarization layer 520. The color conversion layer 520 may include an insulating material. For example, the color planarization layer 520 may include an organic insulating material. An upper surface of the color planarization layer 520 opposite to the device substrate 100 may be a flat surface. For example, the upper surface of the color planarization layer 520 may be parallel to the upper surface of the encapsulation unit 400.

A black matrix 600 may be disposed on the color conversion unit 500. The black matrix 600 may include a material capable of blocking light. For example, the black matrix 600 may include a black dye, such as carbon black. The black matrix 600 may be disposed between the emission areas EA. For example, the pixel areas PA may be disposed side by side in a first direction X and a second direction Y perpendicular to the first direction X, and the black matrix 600 may extend between the pixel areas PA in the first direction X and the second direction Y. The black matrix 600 may include openings overlapping with the emission area EA of each pixel area PA. The black matrix 600 may overlap the bank insulating layer 150. An edge of each pixel area PA may overlap the black matrix 600. For example, the black matrix 600 may overlap an end of each color filter 510. Thus, in the display apparatus according to the embodiment of the present disclosure, the black matrix 600 may prevent the light passing through the color filter 510 of each pixel area PA from emitting through adjacent pixel areas PA. Therefore, in the display apparatus according to the embodiment of the present disclosure, the image by the light emitted from the light-emitting device 300 of each pixel area PA may be clearly separated.

An optical unit or structure 700 may be disposed on the color conversion unit 500 and the black matrix 600. The optical unit 700 may include a plurality of optical lenses 710. The optical lenses 710 may be disposed side by side on the color planarization layer 520. For example, the emission area EA of each pixel area PA may overlap one of the optical lenses 710. The light passing through the opening of the black matrix 600 on each pixel area PA may be condensed by one of the optical lenses 710. For example, a cross-section in a surface of each optical lens 710 opposite to the device substrate 100 may be a semicircular shape. Thus, in the display apparatus according to the embodiment of the present disclosure, frontal luminance of the light emitted from each pixel area PA may be improved.

Each of the optical lenses 710 may extend in a direction. For example, each of the optical lenses 710 may be a lenticular lens having a semi-cylindrical shape and extending in the second direction Y. Each of the optical lenses 710 may overlap two light-emitting devices 300 that are adjacent to each other in the first direction X. For example, the light generated by the two light-emitting devices 300 adjacent in the first direction X may be condensed by a single optical lens 710. Each of the optical lenses 710 may be in direct contact with the upper surface of the color planarization layer 520 exposed by the black matrix 600. Thus, in the display apparatus according to the embodiment of the present disclosure, the right-eye image and the left-eye image may be separated and realized by the optical lenses 710.

Each of the optical lenses 710 may have a same size as adjacent optical lens 710. For example, an edge of each optical lens 710 may be disposed between the pixel areas PA. The black matrix 600 may include a first region 610 disposed between two light-emitting devices 300 overlapping with a single optical lens 710, a second region 620 overlapping with an edge of each optical lens 710, and a third region 630 extending in the first direction X. The first region 610 and the second region 620 may extend in the second direction Y. For example, the third region 630 may intersect the first region 610 and the second region 620. Each of the optical lenses 710 may extend parallel to the first region 610 and the second region 620 of the black matrix 600. For example, the third region 630 of the black matrix 600 may cross each optical lens 710.

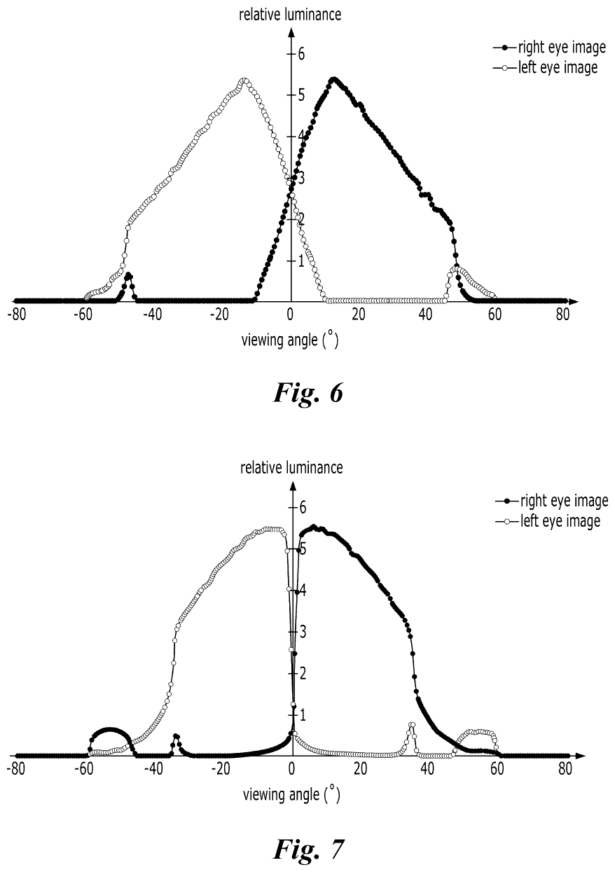

FIG. 6 is a graph showing relative luminance of the right-eye image and the left-eye image realized by the display apparatus in which the black matrix 600 is not arranged between two light-emitting devices 300 overlapping with a single optical lens 710, according to a viewing angle. FIG. 7 is a graph showing relative luminance of the right-eye image and the left-eye image realized by the display apparatus in which the first region 610 of the black matrix 600 is disposed between two light-emitting devices 300 overlapping with a single optical lens 710, according to a viewing angle.

Referring to FIGS. 6 and 7, an overlap between the right-eye image and the left-eye image may be greatly reduced in the frontal direction by the first region 610 of the black matrix 600 between two light-emitting devices 300 overlapping with a single optical lens 710. In general, when the display panel is disposed close to the right-eye lens and the left-eye lens, the right-eye image and the left-eye image realized by the display panel may partially overlap with each other. In the display apparatus according to the embodiment of the present disclosure, each of the optical lenses 710 extending in the second direction Y may overlap two light-emitting device 300 adjacent in the first direction X and the first region 610 of the black matrix 600 which is disposed between the corresponding light-emitting devices 300, such that the right-eye image and the left-eye image of the display panel DP may be effectively separated. That is, in the display apparatus according to the embodiment of the present disclosure, the device body may be slimmed by the right-eye mirror and the left-eye mirror, and the overlap between the right-eye image and the left-eye image realized by the display panel DP may be minimized or reduced by the first region 610 of the black matrix 600. Therefore, in the display apparatus according to the embodiment of the present disclosure, the overall thickness may be slimmed, and the quality of the image recognized by the user may be improved.

The optical unit 700 may include a lens passivation layer 720 on the optical lenses 710, as shown in FIG. 5. The lens passivation layer 720 may prevent damage of the optical lenses 710 due to the external impact. For example, each of the optical lenses 710 may be completely covered by the lens passivation layer 720. The upper surface of each optical lens 710 may be in direct contact with the lens passivation layer 720. The lens passivation layer 720 may include an insulating material. For example, the lens passivation layer 720 may include an organic insulating material. A thickness difference due to the optical lenses 710 may be removed by the lens passivation layer 720. For example, an upper surface of the lens passivation layer 720 opposite to the device substrate 100 may be a flat surface.

The lens passivation layer 720 may have a refractive index same as or greater than each optical lens 710. Thus, in the display apparatus according to the embodiment of the present disclosure, the reflection of the light passing through each optical lens 710 due to a difference in a refractive index of the corresponding optical lens 710 and the lens passivation layer 720 may be prevented. For example, in the display apparatus according to the embodiment of the present disclosure, the light passing through each optical lens 710 may be not reflected toward the device substrate 100 at a boundary surface of the corresponding optical lens 710 and the lens passivation layer 720. Therefore, in the display apparatus according to the embodiment of the present disclosure, a decrease in light-extraction efficiency due to a difference in refractive index may be prevented.

Accordingly, the display apparatus according to the embodiment of the present disclosure may include the display panel DP providing the right-eye image through the right-eye lens 31 and the left-eye image through the left-eye lens 32 to the user, wherein the display panel DP may include the encapsulation unit 400 covering the light-emitting devices 300, the black matrix 600 disposed on the encapsulation unit 400, and the optical lenses 710 disposed on the black matrix, wherein the black matrix 600 may extend between the light-emitting devices 300 in the first direction X and the second direction Y, and wherein each of the optical lenses 710 extending in the second direction Y overlaps at least two light-emitting devices 300 adjacent in the first direction X and the first region 610 of the black matrix 600 disposed between the corresponding light-emitting devices 300. Thus, in the display apparatus according to the embodiment of the present disclosure, the right-eye image and the left-eye image realized by the display panel DP may be effectively separated, without increasing the thickness of the device body 10. That is, in the display apparatus according to the embodiment of the present disclosure, the device body 10 may be slimmed, and the overlap of the right-eye image and the left-eye image realized by the display panel DP may be minimized or reduced by the first region 610 of the black matrix 600. Therefore, in the display apparatus according to the embodiment of the present disclosure, the overall thickness may be reduced, and the quality of the image recognized by the user may be improved.

The display apparatus according to the embodiment of the present disclosure is described that the mounting element 20 has a leg shaped of a glasses frame. However, in the display apparatus according to another embodiment of the present disclosure, the mounting element 20 having various shapes may be used. For example, in the display apparatus according to another embodiment of the present disclosure, the mounting element 20 may have a headgear shape surrounding the user's head. The display apparatus according to another embodiment of the present disclosure may be a wearable display apparatus. Therefore, the display apparatus according to another embodiment of the present disclosure may be mounted on the user in various ways.

The display apparatus according to the embodiment of the present disclosure is described that the pixel driving circuit DC of each pixel area PA consists of the first thin film transistor T1, the second thin film transistor T2 and the storage capacitor Cst. However, in the display apparatus according to another embodiment of the present disclosure, the pixel driving circuit DC of each pixel area PA may include at least one thin film transistor. For example, in the display apparatus according to another embodiment of the present disclosure, the pixel driving circuit DC of each pixel area PA may include the first thin film transistor T1, the second thin film transistor T2, the storage capacitor Cst, and a third thin film transistor. The third thin film transistor may transmit a reference voltage to the storage capacitor Cst according to the gate signal. For example, the third thin film transistor may be a switching thin film transistor. The third thin film transistor may be electrically connected between a reference voltage supply line supplying the reference voltage and the storage capacitor Cst. The third thin film transistor may have a same structure as the first thin film transistor T1. The third thin film transistor may be formed simultaneously with the first thin film transistor T1. Thus, in the display apparatus according to another embodiment of the present disclosure, the degree of freedom in configuring the pixel driving circuit DC in each pixel area PA may be improved.

The display apparatus according to the embodiment of the present disclosure is described that the light-emitting device 300 may be disposed in each pixel area PA of the display panel DP. However, in the display apparatus according to another embodiment of the present disclosure, the display panel DP may include various devices. For example, in the display apparatus according to another embodiment of the present disclosure, the display panel DP may be a liquid crystal panel including a liquid crystal layer. And, in the display apparatus according to another embodiment of the present disclosure, the display panel DP may include a micro-LED. Thus, in the display apparatus according to another embodiment of the present disclosure, the degree of freedom in configuring the display panel DP may be improved.

In the display apparatus according to the embodiment of the present disclosure, the location and the electric connection of the drain electrodes 225 and the source electrode 227 in each pixel area PA may vary depending on the configuration of the pixel driving circuit DC and/or the type of the corresponding thin film transistors T1 and T2 in the corresponding pixel area PA. For example, in the display apparatus according to another embodiment of the present disclosure, the second gate electrode 223 of the second thin film transistor T2 in each pixel area PA may be electrically connected to the first drain electrode of the first thin film transistor T1 in the corresponding pixel area PA. Thus, in the display apparatus according to another embodiment of the present disclosure, the degree of freedom in the configuration of the pixel driving circuit DC in each pixel area PA and the type of the thin film transistors T1 and T2 included in each pixel driving circuit DC may be improved.

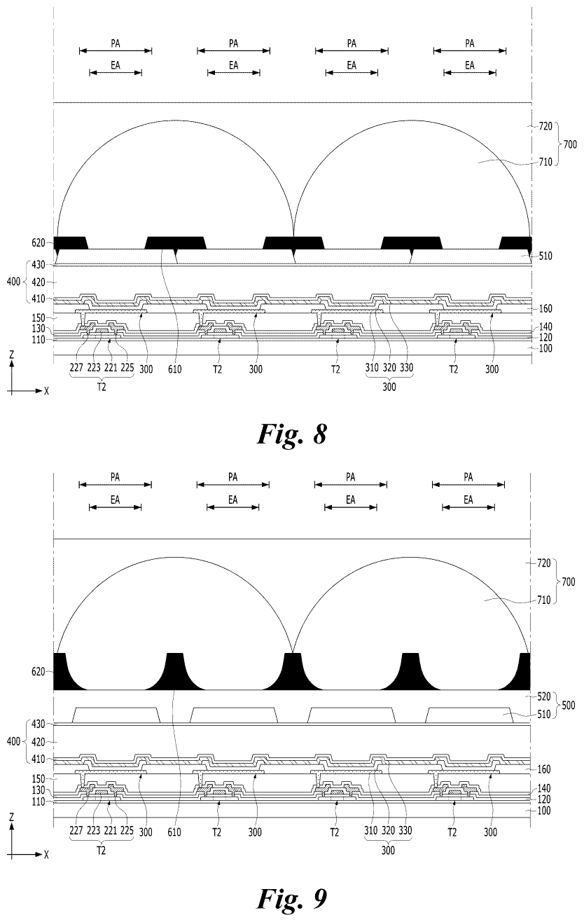

The display apparatus according to the embodiment of the present disclosure is described that the black matrix 600 is disposed on the color planarization layer 520 covering the color filters 510. However, in the display apparatus according to another embodiment of the present disclosure, the black matrix 600 may be in direct contact with an edge of each color filter 510. For example, in the display apparatus according to another embodiment of the present disclosure, an edge of each color filter 510 may overlap an edge of an adjacent color filter 510 between the pixel areas PA, and the black matrix 610 and 620 may be disposed on an overlapping region of the color filters 510, as shown in FIG. 8. Thus, in the display apparatus according to another embodiment of the present disclosure, an overlapping region of the color filters 510 disposed between the pixel areas PA may function as a light-blocking region. Therefore, in the display apparatus according to another embodiment of the present disclosure, mixed color due to mixing of light and light leakage may be effectively prevented. And, in the display apparatus according to another embodiment of the present disclosure, the right-eye image and the left-eye image realized by the display panel may be effectively separated.

The display apparatus according to the embodiment of the present disclosure is described that the light-emitting device 300 of each pixel area PA emits white light. However, in the display apparatus according to another embodiment of the present disclosure, the light emitted from the light-emitting device 300 of each pixel area PA may display a color different from the light emitted from the light-emitting device 300 of adjacent pixel area PA. For example, in the display apparatus according to another embodiment of the present disclosure, the light-emitting devices 300 may include a red light-emitting device emitting the light displaying red color, a blue light-emitting device emitting the light displaying blue color, and a green light-emitting device emitting the light displaying green color. Thus, in the display apparatus according to another embodiment of the present disclosure, color sense realized by each pixel area PA may be improved. Therefore, in the display apparatus according to another embodiment of the present disclosure, the quality of the image recognized by the user may be effectively improved.

The display apparatus according to the embodiment of the present disclosure is described that a cross-section of the black matrix 600 has a trapezoidal shape. However, in the display apparatus according to another embodiment of the present disclosure, a cross-section of the black matrix 600 may have various shapes. For example, in the display apparatus according to another embodiment of the present disclosure, a side of the black matrix 610 and 620 may have a concave shape, as shown in FIG. 9. That is, in the display apparatus according to another embodiment of the present disclosure, the side of the black matrix 610 and 620 may have various curvatures depending on a profile of the light emitted from each light-emitting device 300 and a planar shape of each pixel area PA to realize the right-eye image and/or the left-eye image. Thus, in the display apparatus according to another embodiment of the present disclosure, decrease in the luminance of the image provided to the user may be minimized or reduced, and the right-eye image and the left-eye image realized by a single display panel may be separated.

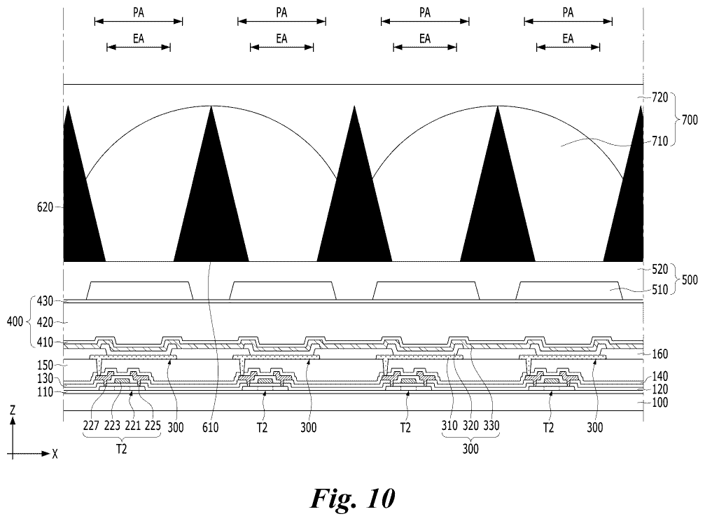

The display apparatus according to the embodiment of the present disclosure is described that the black matrix 600 has a thickness smaller than each optical lens 710. However, in the display apparatus according to another embodiment of the present disclosure, the black matrix 600 may be formed to have various thicknesses. For example, in the display apparatus according to another embodiment of the present disclosure, a thickness of the black matrix 610 and 620 may be the same as a thickness of each optical lens 710, as shown in FIG. 10. Thus, in the display apparatus according to another embodiment of the present disclosure, the light for realizing the right-eye image and the light for realizing the left-eye image, which are emitted from a single display panel, may be effectively separated. And, in the display apparatus according to another embodiment of the present disclosure, mixed color due to mixing of light and light leakage may be effectively prevented.

In the display apparatus according to anther embodiment of the present disclosure, a portion of the black matrix 610 and 620 disposed between the optical lenses 710 may be in direct contact with the lens passivation layer 720. The lens passivation layer 720 may remove a thickness difference due to the black matrix 610 and 620. Thus, in the display apparatus according to another embodiment of the present disclosure, the right-eye image and the left-eye image realized by a single display panel may be effectively separated by the black matrix 610 and 620.

In the result, the display apparatus according to the embodiments of the present disclosure may comprise the display panel providing the right-eye image to the right-eye lens and the left-eye image to the left-eye lens, wherein the display panel may include the black matrix disposed between the encapsulation unit covering the light-emitting devices and the optical lenses, wherein each of the optical lenses may extend in the first direction, and wherein at least two light-emitting devices adjacent in the second direction perpendicular to the first direction and the first region of the black matrix disposed between the corresponding light-emitting devices may overlap one of the optical lenses. Thus, in the display apparatus according to the embodiments of the present disclosure, the overlap of the right-eye image and the left-eye image realized by the display panel may be minimized or reduced. Thereby, in the display apparatus according to the embodiments of the present disclosure, the quality of the image recognized by the user may be improved.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a right-eye lens;
a left-eye lens disposed side-by-side with the right-eye lens; and
a display panel that is operable to provide a right-eye image through the right-eye lens and a left-eye image through the left-eye lens, the display panel including:
a plurality of light-emitting devices on a device substrate;
an encapsulation structure on the plurality of light-emitting devices;
a black matrix on the encapsulation structure; and
a plurality of optical lenses on the black matrix,
wherein the black matrix extends between the plurality of light-emitting devices in a first direction and a second direction perpendicular to the first direction, on a plane,
wherein each of the plurality of optical lenses extended in the second direction overlaps at least two of the plurality of light-emitting devices that are adjacent to each other in the first direction and a first region of the black matrix disposed between the at least two of the plurality of light-emitting devices.

2. The display apparatus according to claim 1, wherein an edge of each of the plurality of optical lenses is disposed between two of the plurality of light-emitting devices that are adjacent each other in the first direction, at least one of which is different from the at least two of the plurality of light-emitting devices overlapping with the corresponding optical lens of the plurality of optical lenses, and
wherein the black matrix includes a second region overlapping with the edge of each optical lens of the plurality of optical lenses.

3. The display apparatus according to claim 1, wherein the first region of the black matrix has a thickness smaller than that of each of the plurality of optical lenses.

4. The display apparatus according to claim 3, wherein the first region of the black matrix has a side surface of a concave shape.

5. The display apparatus according to claim 1, wherein a thickness of the black matrix is the same as a thickness of each of the plurality of optical lenses.

6. The display apparatus according to claim 1, wherein the display panel further includes a plurality of color filters disposed between the plurality of light-emitting devices and the plurality of optical lenses, and
wherein the plurality of color filters is disposed on a layer different from the black matrix.

7. The display apparatus according to claim 6, wherein each of the plurality of color filters includes a region overlapping with the first region of the black matrix.

8. The display apparatus according to claim 6, wherein the display panel further includes a color planarization layer covering the plurality of color filters,
wherein the black matrix is disposed on the color planarization layer, and
wherein an upper surface of the color planarization layer is parallel to an upper surface of the encapsulation structure.

9. The display apparatus according to claim 1, wherein the display panel further includes a lens passivation layer covering the plurality of optical lenses, and
wherein a refractive index of the lens passivation layer is greater than a refractive index of each optical lens of the plurality of optical lenses.

10. The display apparatus according to claim 1, further comprising a device body coupled with the right-eye lens and the left-eye lens, the display panel being accommodated in the device body,
wherein the display panel is disposed between the right-eye lens and the left-eye lens.

11. The display apparatus according to claim 10, further comprising a mounting element extending in a direction from an edge of the device body.

12. The display apparatus according to claim 10, further comprising:
a right-eye mirror reflecting a first light emitted from the display panel toward the right-eye lens to realize the right-eye image; and
a left-eye mirror reflecting a second light emitted from the display panel toward the left-eye lens to realize the left-eye image,
wherein the right-eye mirror and the left-eye mirror are disposed within the device body.

13. The display apparatus according to claim 12, wherein the right-eye mirror and the left-eye mirror are each an aspheric mirror.

14. The display apparatus according to claim 12, wherein the device body includes a first sidewall in which the right-eye lens and the left-eye lens are coupled, and a second sidewall opposite to the first sidewall,
wherein the display panel is disposed closer to the first sidewall than the second sidewall, and
wherein the right-eye mirror and the left-eye mirror are disposed closer to the second sidewall than the first sidewall.

15. The display apparatus according to claim 12, wherein a distance between the right-eye mirror and the display panel is larger than a distance between the right-eye lens and the display panel.

16. The display apparatus according to claim 12, wherein a distance between the left-eye mirror and the display panel is larger than a distance between the left-eye lens and the display panel.

17. A display panel, comprising:
a device substrate;
a plurality of light-emitting devices on the device substrate, the plurality of light-emitting devices including:
a first light-emitting device; and
a second light-emitting device adjacent the first light-emitting device along a first direction;
a black matrix on the plurality of light-emitting devices, the black matrix including a first region between the first light-emitting device and the second light-emitting device, the first region extending in a second direction transverse the first direction; and
an optical lens extending in the second direction and being over and covering the first light-emitting device, the second light-emitting device and the first region of the black matrix.

18. The display panel of claim 17, wherein the black matrix further includes a second region adjacent to and separated from the first region by the first light-emitting device, an edge of the optical lens overlapping the second region.

19. A display apparatus, comprising:
a first lens;
a second lens spaced from the first lens;
a first mirror operable to reflect first light toward the first lens to realize a first image; and
a second mirror operable to reflect second light toward the second lens to realize a second image;
a display panel between the first lens and the second lens, the display panel being operable to generate the first light and the second light, the display panel including:
a device substrate;
a first light-emitting device on the device substrate;
a second light-emitting device on the device substrate, the second light-emitting device being adjacent the first light-emitting device along a first direction;
a black matrix on first and second light-emitting devices, the black matrix including a first region between the first light-emitting device and the second light-emitting device, the first region extending in a second direction transverse the first direction; and
an optical lens extending in the second direction and being over and covering the first light-emitting device, the second light-emitting device and the first region of the black matrix.

20. The display apparatus of claim 19, wherein the display panel further includes:
a first color filter disposed between the first light-emitting device and the optical lens; and
a second color filter disposed between the second light-emitting device and the optical lens;
wherein the first region of the black matrix is in direct contact with respective sidewalls of the first and second color filters.
